(19) United States
(12) Patent Application Publication
(10) Pub. No.: US 2025/0021008 A1
(43) Pub. Date: Jan. 16, 2025

(54) TOP MODULE AND EXPOSING APPARATUS INCLUDING THE SAME

(71) Applicant: Samsung Electronics Co., Ltd., Suwon-si (KR)

(72) Inventors: Yebin Nam, Suwon-si (KR); Sunghyup Kim, Suwon-si (KR); Injae Lee, Suwon-si (KR)

(21) Appl. No.: 18/403,030

(22) Filed: Feb. 7, 2024

(30) Foreign Application Priority Data
Jul. 13, 2023 (KR) 10-2023-0091069

(51) Int. Cl. G03F 7/00

(52) U.S. Cl. CPC G03F 7/70066; G03F 7/70033; G03F 7/70741; G03F 7/70866; G03F 7/70916

(57) ABSTRACT

A top module of an exposing apparatus may include a reticle stage, a nozzle and a pair of guides. The reticle stage may be configured to support a reticle to which a light is incident. The nozzle may be under the reticle stage and configured to inject a shielding gas in a first horizontal direction. The guides may extend from opposite sides of the nozzle and may be configured to induce the shielding gas in the first horizontal direction. Thus, the shielding gas may not diffuse in a second horizontal direction (e.g., perpendicular to the first horizontal direction) to prevent a diffusion of a contaminant in the shielding gas, thereby preventing the reticle from being contaminated. As a result, a pattern of the reticle may be accurately transcribed into a layer on a semiconductor substrate to form a desired pattern.

### CROSS-RELATED APPLICATION

This application claims priority under 35 USC § 119 to Korean Patent Application No. 10-2023-0091069, filed on Jul. 13, 2023 in the Korean Intellectual Property Office (KIPO), the contents of which are herein incorporated by reference in their entirety.

### BACKGROUND

Example embodiments relate to a top module and an exposing apparatus including the same. More particularly, example embodiments relate to a top module configured to control an extreme ultraviolet (EUV) light incident to a reticle, and an exposing apparatus including the top module.

Generally, an exposing apparatus using an EUV light may include a top module configured to control the EUV light incident to a reticle. The EUV light may be incident to a semiconductor substrate through the reticle.

According to related arts, in order to prevent a contamination of the reticle, a shielding gas such as a hydrogen gas may be injected to the reticle. However, a part of the shielding gas may diffuse in a radial direction, rather than flow along an initial injection direction. Contaminants in the radially diffusing shielding gas may contaminate the reticle.

### SUMMARY

Example embodiments provide a top module that may be capable of preventing a shielding gas from diffusing in a radial direction.

Example embodiments also provide an exposing apparatus including the above-mentioned top module.

According to example embodiments, there may be provided a top module of an exposing apparatus. The top module may include a reticle stage, a nozzle and a pair of guides. The reticle stage may be configured to support a reticle configured to receive a light (e.g., to which a light is incident). The nozzle may be under the reticle stage and configured to inject a shielding gas in a first horizontal direction. The guides may extend from opposite sides of the nozzle and may be configured to induce the shielding gas in the first horizontal direction.

According to example embodiments, there may be provided a top module of an exposing apparatus. The top module may include a reticle stage, a nozzle, first and second guides, a first blade and a pair of second blades. The reticle stage may be configured to support a reticle configured to receive a light (e.g., to which an extreme ultraviolet (EUV) light is incident). The nozzle may be under the reticle stage and configured to inject a shielding gas in a first horizontal direction. The first and second guides may extend from first and second opposite sides of the nozzle in the first horizontal direction and configured to induce the shielding gas in the first horizontal direction. The first blade may be under the nozzle and extend in the first horizontal direction. The first blade may have an opening configured to expose a region of the reticle to which the light may be irradiated. The second blades may be movably over the first blade in a second horizontal direction, which may be substantially perpendicular to the first horizontal direction, to control a size of the opening.

According to example embodiments, there may be provided a top module of an exposing apparatus. The top module may include a reticle stage, a nozzle, first and second guides and a first blade. The reticle stage may be configured to support a reticle configured to receive a light (e.g., to which an extreme ultraviolet (EUV) light is incident). The nozzle may be under the reticle stage and configured to inject a shielding gas. The first and second guides may extend from first and second opposite sides of the nozzle and configured to induce the shielding gas. The first blade may be under the nozzle. The first blade may have an opening configured to expose a region of the reticle to which the light may be irradiated.

According to example embodiments, there may be provided an exposing apparatus. The exposing apparatus may include a reticle stage, a substrate stage, an illuminating optical module, a projecting optical module, a nozzle and a pair of guides. The reticle stage may be configured to support a reticle. The substrate stage may be configured to support a substrate. The illuminating optical module may transfer a light to the reticle stage. The projecting optical module may be configured to transfer the light, which may pass through the reticle on the reticle stage, to the substrate stage. The nozzle may be under the reticle stage and configured to inject a shielding gas in a first horizontal direction. The guides may extend from opposite sides of the nozzle and may be configured to induce the shielding gas in the first horizontal direction.

According to example embodiments, the pair of the guides extending in the first horizontal direction may induce or guide the shielding gas injected from the nozzle in the first horizontal direction. Thus, the shielding gas may not diffuse in the second horizontal direction to prevent a diffusion of a contaminant in the shielding gas, thereby preventing the reticle from being contaminated. As a result, a pattern of the reticle may be accurately transcribed into a layer on a semiconductor substrate to form a desired pattern.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

FIG. 1 is a view illustrating an exposing apparatus in accordance with example embodiments;

FIG. 2 is a cross-sectional view illustrating a top module of the exposing apparatus in FIG. 1;

FIG. 3 is a plan view illustrating the top module in FIG. 2;

FIG. 4 is an enlarged perspective view illustrating an upper structure of the top module in FIG. 2;

FIG. 5 is an enlarged perspective view illustrating a lower structure of the top module in FIG. 2;

FIG. 6 is an enlarged perspective view illustrating a nozzle and guides of the top module in FIG. 2;

FIG. 7 is an enlarged perspective view illustrating a nozzle and guides of a top module in accordance with example embodiments;

FIG. 8 is an image showing a flow of a shielding gas in a top module in accordance with Comparative Example; and

FIG. 9 is an image showing a flow of a shielding gas in a top module in accordance with example embodiments.

### DETAILED DESCRIPTION

Hereinafter, example embodiments will be explained in detail with reference to the accompanying drawings.

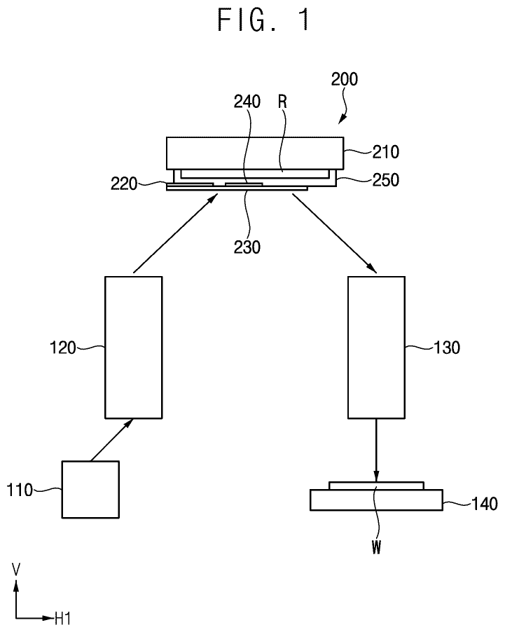

FIG. 1 is a view illustrating an exposing apparatus in accordance with example embodiments.

Referring to FIG. 1, an exposing apparatus of example embodiments may include a light source 110, an illuminating optical module 120, a top module 200, a projecting optical module 130 and a substrate stage 140.

The light source 110 may generate a light. In example embodiments, the light source 110 may generate an extreme ultraviolet (EUV) light, but is not limited thereto. The EUV light generated from the light source 110 may be irradiated to the illuminating optical module 120. The EUV light may have a wavelength of about 1 nm to about 31 nm. For example, the wavelength of the EUV light may be about 10 nm to about 14 nm.

The illuminating optical module 120 may include a first optical module. The first optical module may condense the EUV light. The first optical module may then transfer the EUV light to the top module 200. The first optical module may uniformly control a path of the EUV light. The first optical module may include a convex mirror, a concave mirror, a combination thereof, etc., to provide the EUV light with various paths. The illuminating optical module 120 may include an independent vacuum chamber.

The top module 200 may control the EUV light incident to a reticle R. Further, the top module 200 may move the reticle R in a horizontal direction to control positions of the reticle R. For example, the top module 200 with the reticle R may be moved in the horizontal direction using an electrostatic chuck (ESC). The reticle R may be mounted on a lower surface of the top module 200 to orient a surface of the reticle R on which an optical pattern may be formed in a downward direction. The EUV light transferred from the illuminating optical module 120 may be irradiated to a surface of the reticle R. The EUV light reflected from the reticle R on the top module 200 may be transferred to the projecting optical module 130.

The projecting optical module 130 may transfer the EUV light to the substrate stage 140. The projecting optical module 130 may include a second optical module. The second optical module may correct various aberrations. The second optical module may include a plurality of concave mirrors.

The substrate stage 140 may support a substrate W. The substrate stage 140 may move the substrate W in the horizontal direction to control positions of the substrate W. For example, the substrate stage 140 with the substrate W may be moved in the horizontal direction using the ESC. Thus, the projecting optical module 130 may demagnify and project patterns of the reticle R on the substrate W.

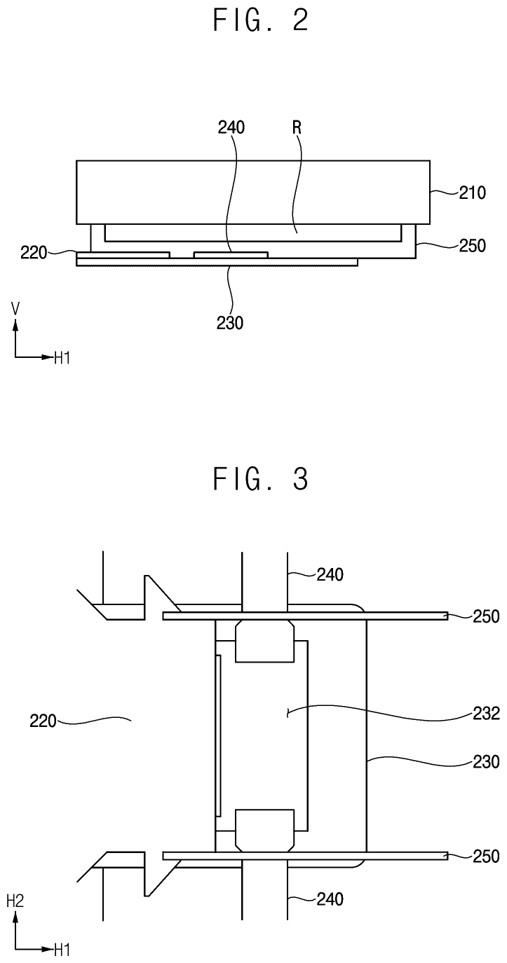

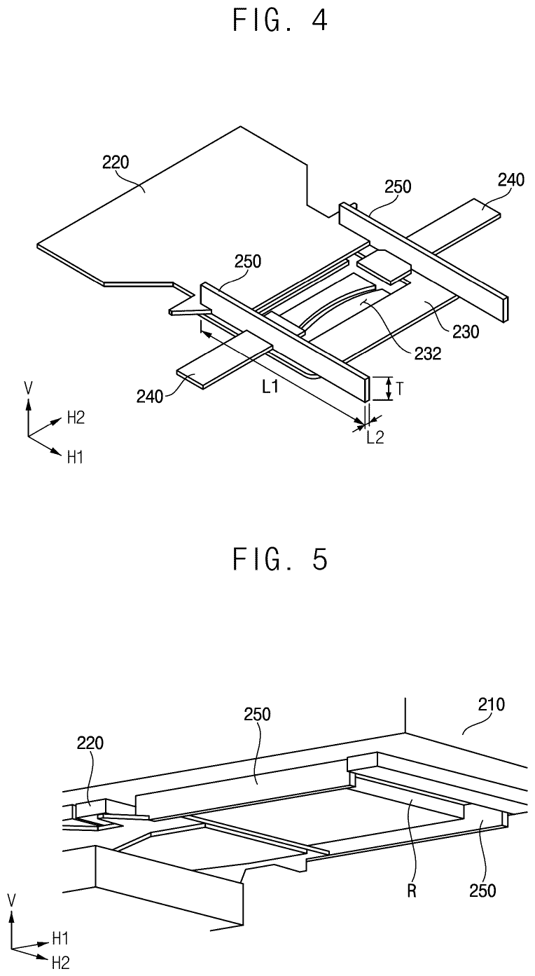

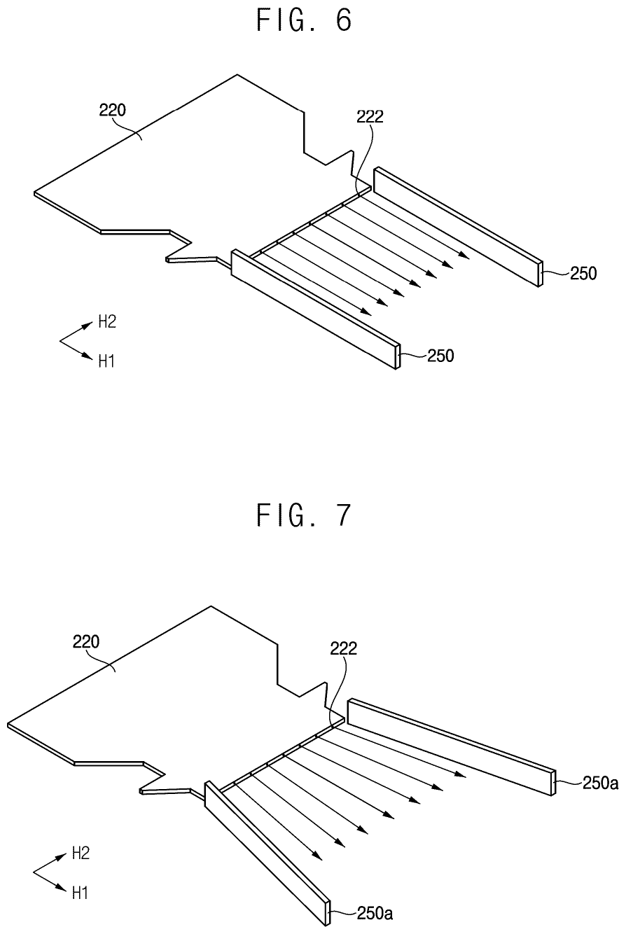

FIG. 2 is a cross-sectional view illustrating a top module of the exposing apparatus in FIG. 1, FIG. 3 is a plan view illustrating the top module in FIG. 2, FIG. 4 is an enlarged perspective view illustrating an upper structure of the top module in FIG. 2, FIG. 5 is an enlarged perspective view illustrating a lower structure of the top module in FIG. 2 and FIG. 6 is an enlarged perspective view illustrating a nozzle and guides of the top module in FIG. 2.

Referring to FIGS. 2 to 6, the top module 200 may include a reticle stage 210, a nozzle 220, a first blade 230, a pair of second blades 240 and a pair of guides 250.

The reticle stage 210 may be placed between the illuminating optical module 120 and the projecting optical module 130. The reticle stage 210 may support the reticle R to which the EUV light may be incident. The reticle R may be arranged on a lower surface of the reticle stage 210. In order to irradiate the EUV light passing through the reticle R to a desired region of the semiconductor substrate W on the substrate stage 140, the reticle stage 210 may be moved in a first horizontal direction H1 and a second horizontal direction H2 perpendicular or substantially perpendicular to each other. The first horizontal direction H1 may correspond to an X-direction. The second horizontal direction H2 may correspond to a Y-direction.

The nozzle 220 may be arranged under the reticle stage 210. The nozzle 220 may include a plurality of injection holes 222. The injection holes 222 may inject a shielding gas to a space under the reticle stage 210 in the first horizontal direction H1. Thus, the nozzle 220 may correspond to a Y-nozzle. The shielding gas may prevent contaminants from being smeared on the reticle R. The shielding gas may include a hydrogen gas, but is not limited thereto.

The first blade 230 may be arranged under the nozzle 220. The first blade 230 may be extended in the first horizontal direction H1. Further, the first blade 230 may have an opening 232 configured to selectively expose the reticle R. Thus, regions of the reticle R to which the EUV light may be irradiated may be controlled by adjusting positions of the opening 232.

The second blades 240 may be arranged over the first blade 230. The second blades 240 may be selectively moved in the second horizontal direction H2 to control a size of the opening 232 of the first blade 230. Thus, sizes of the regions on the reticle R to which the EUV light may be irradiated may be controlled by selectively moving the second blades 240 in the second horizontal direction H2.

The pair of the guides 250 (or first and second guides) may be extended from both or opposite ends or sides of the nozzle 220. Particularly, the guides 250 may be extended from the ends or first and second opposite sides of the nozzle 220 in the first horizontal direction H1. The guides 250 may induce the shielding gas injected from the nozzle 220 in the first horizontal direction H1. That is, the guides 250 may prevent a diffusion of the shielding gas in a direction inclined to the first horizontal direction H1, particularly, the second horizontal direction H2 to suppress the reticle R from being contaminated by contaminants in the reticle R. The guides 250 may have substantially the same shape and size, but are not limited thereto.

In example embodiments, the guides 250 may be integrally formed with the nozzle 220. Alternatively, the guides 250 may be parts attached to the nozzle 220.

In example embodiments, each of the guides 250 may have a rectangular parallelepiped shape, but are not limited thereto. Particularly, the guide 250 may have a first length L1 along the first horizontal direction H1, a second length or width L2 along the second horizontal direction H2 and a length along a vertical direction V corresponding to a Z-direction, i.e., a height T. The height T may be longer than the second length L2 so that the guide 250 may have the rectangular parallelepiped shape having a relatively large height. Particularly, in order to cover whole outer side surfaces of the reticle R by the guide 250, the first length L1 of the guide 250 may be no less than a length of the reticle R.

In example embodiments, a gap between the pair of the guides 250, i.e., the gap between guides 250 along the second horizontal direction H2 may be uniform. Further, the length of the guide 250 along the vertical direction, i.e., the height T of the guide 250 may be greater than a thickness of the nozzle 220. Thus, the guides 250 may be upwardly and downwardly extend or protrude from the nozzle 220 to prevent the diffusion of the shielding gas.

Further, the pair of the guides 250 may have inner side surfaces substantially parallel to both outer side surfaces of the reticle R, but are not limited thereto. For example, the inner side surfaces of the guides 250 may be slant to or toward the outer side surfaces of the reticle R. Further, the inner side surfaces of the guides 250 may make contact with the outer side surfaces of the reticle R. Alternatively, a gap may be formed between the inner side surfaces of the guides 250 and the outer side surfaces of the reticle R.

In example embodiments, the inner side surfaces of the guides 250 may cover the outer side surfaces of the reticle R to prevent the whole outer side surfaces of the reticle R from being exposed, but are not limited thereto. For example, the inner side surfaces of the guides 250 may partially cover the outer side surfaces of the reticle R to partially expose the outer side surfaces of the reticle R. Particularly, the pair of the guides 250 may have upper ends substantially coplanar with an upper surface of the reticle R, but are not limited thereto. For example, the upper ends of the guides 250 may be positioned above or under the upper surface of the reticle R.

FIG. 7 is an enlarged perspective view illustrating a nozzle and guides of a top module in accordance with example embodiments.

Referring to FIG. 7, a gap between a pair of guides 250a of example embodiments, i.e., the gap between the guides 250a in the second horizontal direction H2 may gradually widen along the first horizontal direction H1, e.g., in a direction away from the nozzle 220.

In example embodiments, the gap between the guides 250 and 250a may be uniform or gradually widen, but is not limited thereto. For example, each of a pair of guides may have at least one bent portion to form at least two gaps between the guides.

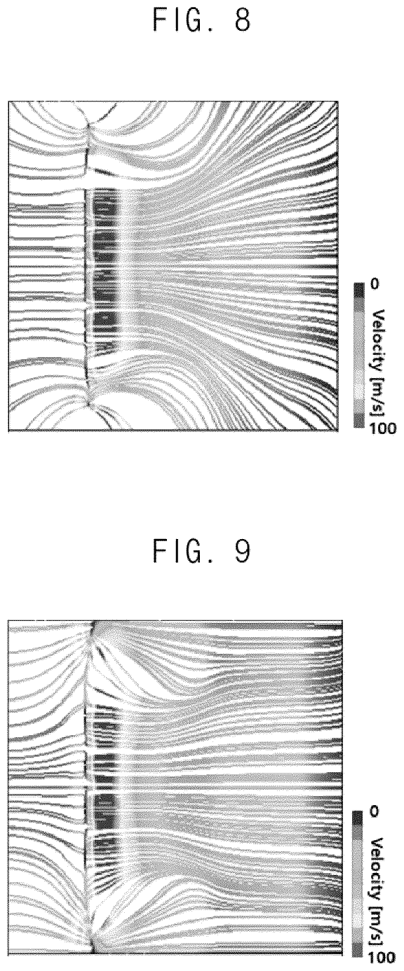

FIG. 8 is an image showing a flow of a shielding gas in a top module in accordance with Comparative Example and FIG. 9 is an image showing a flow of a shielding gas in a top module in accordance with example embodiments.

As shown in FIG. 8, in a structure without the guide 250, it can be noted that a part of the shielding gas may diffuse the direction inclined to the first horizontal direction H1. Thus, the reticle R may be contaminated by the contaminant in the shielding gas.

In contrast, as shown in FIG. 9, in the structure with the guide 250, it can be noted that all the shielding gas may flow along the first horizontal direction H1. Thus, the diffusion of the shielding gas may be blocked by the guides 250 to prevent the reticle R from being contaminated.

According to example embodiments, the pair of the guides extended in the first horizontal direction may induce or direct or guide the shielding gas injected from the nozzle in the first horizontal direction. Thus, the shielding gas may not diffuse in the second horizontal direction to prevent a diffusion of a contaminant in the shielding gas, thereby preventing the reticle from being contaminated. As a result, a pattern of the reticle may be accurately transcribed into a layer on a semiconductor substrate to form a desired pattern.

The foregoing is illustrative of example embodiments and is not to be construed as limiting thereof. Although a few example embodiments have been described, those skilled in the art will readily appreciate that many modifications are possible in the example embodiments without departing from the novel teachings and advantages of the present disclosure. Accordingly, all such modifications are intended to be included within the scope of the present disclosure as defined in the claims.

What is claimed is:

1. A top module of an exposing apparatus comprising:
a reticle stage configured to support a reticle to which a light is incident;
a nozzle under the reticle stage and configured to inject a shielding gas in a first horizontal direction; and
a pair of guides extending from opposite sides of the nozzle and configured to induce the shielding gas in the first horizontal direction.

2. The top module of the exposing apparatus of claim 1, wherein the pair of the guides extend in the first horizontal direction.

3. The top module of the exposing apparatus of claim 2, wherein a gap between the pair of the guides along a second horizontal direction substantially perpendicular to the first horizontal direction is uniform along the first horizontal direction.

4. The top module of the exposing apparatus of claim 2, wherein a gap between the pair of the guides along a second horizontal direction substantially perpendicular to the first horizontal direction gradually widens along the first horizontal direction away from the nozzle.

5. The top module of the exposing apparatus of claim 1, wherein the pair of the guides have a height greater than a thickness of the nozzle.

6. The top module of the exposing apparatus of claim 1, wherein each of the guides has a length of no less than a length of the reticle along the first horizontal direction.

7. The top module of the exposing apparatus of claim 1, wherein the pair of the guides have inner side surfaces substantially parallel to outer side surfaces of the reticle.

8. The top module of the exposing apparatus of claim 7, wherein the inner side surfaces of the pair of the guides cover the outer side surfaces of the reticle.

9. The top module of the exposing apparatus of claim 8, wherein the pair of the guides have upper ends substantially coplanar with an upper surface of the reticle.

10. The top module of the exposing apparatus of claim 1, further comprising a first blade under the nozzle and extending in the first horizontal direction,
wherein the first blade has an opening configured to expose a region of the reticle to which the light is irradiated.

11. The top module of the exposing apparatus of claim 10, further comprising a pair of second blades movable over the first blade and extending in a second horizontal direction, which is substantially perpendicular to the first horizontal direction, to control a size of the opening.

12. A top module of an exposing apparatus comprising:
a reticle stage configured to support a reticle to which an extreme ultraviolet (EUV) light is incident;
a nozzle under the reticle stage and configured to inject a shielding gas in a first horizontal direction;
first and second guides extending from first and second opposite sides of the nozzle along the first horizontal direction and configured to induce the shielding gas in the first horizontal direction;
a first blade under the nozzle and extending in the first horizontal direction, the first blade having an opening configured to expose a region of the reticle to which the light is irradiated; and
a pair of second blades movable over the first blade in a second horizontal direction, which is substantially perpendicular to the first horizontal direction, to control a size of the opening.

13. The top module of the exposing apparatus of claim 12, wherein a gap between the first and second guides along the second horizontal direction is uniform along the first horizontal direction.

14. The top module of the exposing apparatus of claim 12, wherein a gap between the first and second guides along the second horizontal direction gradually widens along the first horizontal direction away from the nozzle.

15. The top module of the exposing apparatus of claim 12, wherein the first and second guides have a height greater than a thickness of the nozzle.

16. The top module of the exposing apparatus of claim 12, wherein each of the first and second guides has a length of no less than a length of the reticle along the first horizontal direction.

17. A top module of an exposing apparatus comprising:
a reticle stage configured to support a reticle to which an extreme ultraviolet (EUV) light is incident;
a nozzle under the reticle stage and configured to inject a shielding gas;
first and second guides extending from first and second opposite sides of the nozzle and configured to induce the shielding gas; and
a first blade under the nozzle, the first blade having an opening configured to expose a region of the reticle to which the light is irradiated.

18. The top module of the exposing apparatus of claim 17, wherein the nozzle injects the shielding gas in a first horizontal direction, the first and second guides extend along the first horizontal direction to induce the shielding gas in the first horizontal direction, and the first blade extends in the first horizontal direction.

19. The top module of the exposing apparatus of claim 18, further comprising a pair of second blades movable over the first blade in a second horizontal direction, which is substantially perpendicular to the first horizontal direction, to control a size of the opening.

20. The top module of the exposing apparatus of claim 19, wherein a gap between the first and second guides along the second horizontal direction is uniform along the first horizontal direction.
